(19) United States
(12) Patent Application Publication
(10) Pub. No.: US 2020/0378752 A1
(43) Pub. Date: Dec. 3, 2020

(54) DEVICES AND METHODS TO MEASURE SMALL DISPLACEMENTS

(71) Applicant: YEDA RESEARCH AND DEVELOPMENT CO. LTD., Rehovot (IL)

(72) Inventors: Igor LUBOMIRSKY, Petach-Tikva (IL); Guy LAZOVSKI, Rehovot (IL)

(73) Assignee: YEDA RESEARCH AND DEVELOPMENT CO. LTD., Rehovot (IL)

(21) Appl. No.: 16/071,089

(22) PCT Filed: Jan. 19, 2017
(86) PCT No.: PCT/IL2017/050074

§ 371 Date: Jul. 19, 2018

(30) Foreign Application Priority Data
Jan. 20, 2016 (IL) 243712

(51) Int. Cl. G01B 11/16; G01N 25/16; G01N 21/21; G01N 21/17

(52) U.S. Cl. CPC G01B 11/168; G01N 25/16; G01N 21/211; G01R 29/22; G01N 2201/063; G01N 2021/1731; G01N 21/1717

(57) ABSTRACT

Methods, devices and apparatus for measuring expansion/contraction properties of a material are described. According to an embodiment a method comprises: providing a device, said device comprising a sample comprising said material, said sample comprising a first surface and a second surface, a first substrate and a second substrate connected to said first surface and to said second surface of said sample, respectively, a reflective material attached to said second substrate, and two electrical contacts each independently in contact with said sample; applying voltage to said sample using said electrical contacts; illuminating said reflective material using a light source, such that said illumination comprises light having known and controllable polarization; collecting light reflected off said reflective material; measuring amplitude and phase of an oscillating change in polarization of the reflected light; and extracting parameters related to expansion/contraction from said reflected light measurement, thus evaluating said expansion/contraction properties of said material.

### FIELD OF THE INVENTION

This invention relates to a device for the measurement of expansion/contraction of materials (such as in electro-mechanic effects, thermal expansion etc.) and to apparatuses and methods for measuring such properties.

### BACKGROUND OF THE INVENTION

Null ellipsometry known at least since 1888, has been used as a technique for the investigation of dielectric properties and thicknesses of film stacks. In the course of time it was also utilized for the investigation of several surface processes such as etching, oxidation, adsorption etc. In addition, the null ellipsometer was modified both equipment wise and methodology wise, enabling it to monitor several electro-optical effects in poled polymer films and in thermally grown silicon oxide. These represent the optical manifestation of the materials' electromechanical activity such as, Pockels effect for piezoelectric materials and Kerr effect for electrostrictors. Recently it was also found to be a powerful tool for the investigation of oxygen conduction in ion-conducting and mixed ionic/electronic conducting materials.

All methods described above, relies on the interaction between polarized light and the material to be tested. The light penetrates the material or interacts with the material's surface. This interaction causes modification of the light polarization. When the light is reflected back from the material, a polarizer and a detector are used for measuring the polarization change, thus evaluating properties of the material.

### SUMMARY OF THE INVENTION

In this invention, a novel method of investigating a material is presented. The method utilizes polarized light that in contrast to conventional methods does not interact directly with the material or with the material's surface. In the methods of this invention, the material to be tested is secured underneath a reflective material, such that the polarized light, that illuminates and reflected off the reflective material, does not interact with the investigated material itself. Accordingly, the polarized light is only affected by expansion/contraction of the material that displaces the reflective material, but is not affected by material's properties such as refractive index and surface-layer composition/thickness. The novel methods of this invention thus allow the isolation of expansion/contraction parameters of a material. Accordingly, the methods of this invention allow facile, fast and accurate measurement of expansion/contraction properties of a material using polarized light.

In one embodiment, this invention provides devices, methods and apparatuses that utilize polarized light, to track expansion/contraction properties of a material.

In one embodiment, this invention provides a device for the measurement of expansion/contraction properties of a material, the device comprising:
a first sample comprising a first material, the sample comprising a first surface and a second surface;
a first substrate and a second substrate, connected to the first surface and to the second surface of the sample respectively;
a second sample comprising a second material in contact with the second substrate;
a third substrate connected to the second sample;
a reflective material in contact with the third substrate.

In one embodiment, the device further comprises an adhesive in contact with the third substrate and in contact with the reflective material such that the reflective material is attached to the third substrate via the adhesive material. In one embodiment, the device further comprises a first set of two electrical contacts each independently is in contact with the first sample and a second set of two electrical contacts each independently is in contact with the second sample. In one embodiment, the device further comprises a heating source for heating the first sample, the second sample or a combination thereof.

In one embodiment, one of the first material and the second material possesses known expansion/contraction properties and another of the first material and the second material possesses un-known expansion/contraction properties.

In one embodiment, the first material and the second material possess piezoelectric properties, electrostriction properties, thermal expansion properties or a combination thereof.

In one embodiment, the heating source comprises IR laser. In one embodiment, the reflective material is reflective at a certain wavelength. In one embodiment, the wavelength is 632.8 nm. In one embodiment, the thickness of the sample ranges between 1 nanometer to 100 millimeters. In one embodiment, the thickness of the substrate ranges between 10 micrometers to 100 millimeter. In one embodiment, the thickness of the adhesive ranges between from 1 nanometer to 1 millimeter. In one embodiment, the thickness of the reflective material ranges between from 1 micrometer to 100 millimeter. In one embodiment, the thickness of the reflective material ranges between from 275 micrometer to 50 millimeter. According to this aspect and in one embodiment, the second substrate is sufficiently flat and polished and it acts as the reflective material. Accordingly, in some embodiments, at least one of the substrates is a reflective material, and no additional reflective material is needed for devices and methods of this invention.

In one embodiment, the thickness of the electrical contacts ranges between from 1 nanometer to 10 millimeters. In one embodiment, the reflective material is attached to the substrate via the adhesive material. In one embodiment, the adhesive material comprises modeling clay. In one embodiment, the first substrate, second substrate or a combination thereof comprises alumina. In one embodiment, the electrical contacts comprise Ag, Au, Cu, Pd. Pt, Sn or a combination thereof. In one embodiment, the electrical contacts comprise conductive paint such as silver paint.

In one embodiment, this invention provides a system for the measurement of expansion/contraction properties of a material, the system comprising:
a device comprising:
   a sample comprising the material, the sample comprising a first surface and a second surface;
   a first substrate and a second substrate, connected to the first surface and to the second surface of the sample respectively;
   optionally two electrical contacts, each independently is in contact with said sample;
   optionally a heating source for heating said sample;
or:
a device comprising:
   a first sample comprising a first material, the sample comprising a first surface and a second surface;
   a first substrate and a second substrate, connected to the first surface and to the second surface of the sample respectively;
   a second sample comprising a second material in contact with the second substrate;
   a third substrate connected to the second sample;
   optionally, a first set of two electrical contacts each independently is in contact with said first sample and a second set of two electrical contacts each independently is in contact with said second sample;
   optionally a heating source for heating said first sample, said second sample or a combination thereof;
a base;
a movable arm comprising a first and a second end;
a spring;
a reflective material attached to the top surface of the arm;
wherein the first end of the movable arm is associated with the base; said second end (or a portion close to the second end) of the movable arm is associated with the spring; the spring is attached to the base; and the device is located on top of the base and under the movable arm.

In one embodiment, this invention provides a method of measuring expansion/contraction properties of a material, the method comprising:
providing a device comprising:
   a sample comprising said material, said sample comprising a first surface and a second surface;
   a first substrate and a second substrate, connected to the first surface and to the second surface of the sample respectively;
   a reflective material attached to the second substrate;
   optionally two electrical contacts, each independently is in contact with the sample;
   optionally a heating source for heating said sample;
optionally applying voltage to the sample using the electrical contacts;
optionally heating said sample;
illuminating the reflective material using a light source, such that said illumination comprises light having known and controllable polarization;
collecting light reflected off the reflective material;
measuring amplitude and phase of the oscillating change in polarization of the reflected light;
extracting parameters related to expansion/contraction from the reflected light measurement, thus evaluating said expansion/contraction properties of the material.

In one embodiment, the device in systems and methods of this invention further comprises an adhesive in contact with the substrate and in contact with the reflective material such that the reflective material is attached to the substrate via the adhesive material.

In one embodiment, the light source is a He—Ne laser. In one embodiment, collecting the reflected light is done using a detector. In one embodiment, the method allows qualitative evaluation of the expansion/contraction properties.

In one embodiment, this invention provides a method of measuring expansion/contraction properties of a material, the method comprising:
providing a device comprising:
   a first sample comprising a first material, the sample comprising a first surface and a second surface;
   a first substrate and a second substrate, connected to the first surface and to the second surface of the sample respectively;
   a second sample comprising a second material in contact with the second substrate;
   a third substrate connected to the second sample;
   a reflective material in contact with the third substrate;
   optionally, a first set of two electrical contacts each independently is in contact with the first sample and a second set of two electrical contacts each independently is in contact with the second sample;
   optionally a heating source for heating the first sample, the second sample or a combination thereof;
measuring the first sample, the measurement comprising:
   optionally applying voltage to the first sample using the electrical contacts;
   optionally heating the first sample using the heating source;
   illuminating the reflective material with a light source, such that said illumination comprises light having known and controllable polarization;
   collecting light reflected off the reflective material;
   measuring amplitude and phase of the oscillating change in polarization of the reflected light;
   extracting parameters related to expansion/contraction from the reflected light measurement, thus evaluating the expansion/contraction properties of the material.
measuring the second sample, the measurement comprising:
   optionally applying voltage to the second sample using the electrical contacts;
   optionally heating the second sample using the heating source;
   illuminating the reflective material with a light source;
   collecting light reflected off the reflective material;
   measuring amplitude and phase of the oscillating change in polarization of the reflected light;
   extracting parameters related to expansion/contraction from the reflected light measurement, thus evaluating the expansion/contraction properties of said material.
comparing parameters extracted from the first sample measurement to parameters extracted from the second sample measurement, thus evaluating the expansion/contraction properties of the material.

In one embodiment, the device further comprises an adhesive in contact with the third substrate and in contact with the reflective material such that the reflective material is attached to the third substrate via the adhesive material.

In one embodiment, the step of measuring the second sample is conducted prior to the step of measuring the first sample.

In one embodiment, one of the first material and the second material possesses known expansion/contraction properties and another of the first material and the second material possesses un-known expansion/contraction properties.

In one embodiment, the method allows quantitative evaluation of the expansion/contraction properties of the material. In one embodiment, the quantitative evaluation comprises evaluation of the piezo-electric coefficient or electrostriction coefficient of the material. In one embodiment, the method allows qualitative evaluation of the expansion/contraction properties of the material.

In one embodiment, this invention provides an apparatus for the measurement of expansion/contraction properties of a material, the apparatus comprising:
a first device or a second device, wherein:
   the first device comprising:
      a sample comprising the material, the sample comprising a first surface and a second surface;
      a first substrate and a second substrate, connected to the first surface and to the second surface of the sample respectively;
      an adhesive in contact with the second substrate;
      a reflective material in contact with the adhesive;
      optionally two electrical contacts, each independently is in contact with the sample;
      optionally a heating source for heating the sample;
      the second device comprising:
      a first sample comprising a first material, the sample comprising a first surface and a second surface;
      a first substrate and a second substrate, connected to the first surface and to the second surface of the sample respectively;
      a second sample comprising a second material in contact with the second substrate;
      a third substrate connected to the second sample;
      an adhesive in contact with the third substrate;
      a reflective material in contact with the adhesive;
      optionally, a first set of two electrical contacts each independently is in contact with the first sample and a second set of two electrical contacts each independently is in contact with the second sample;
      optionally a heating source for heating the first sample, the second sample or a combination thereof;
light source for illuminating the reflective material;
a first polarizer for polarizing the light;
optionally a quarter wave plate;
a second polarizer for polarizing light reflected off the reflective material;
detector for collecting light reflected off the reflective material;
optionally a power supply for applying voltage to the sample;
means for measuring amplitude and phase of the oscillating change in polarization of the reflected light;
means for extracting parameters related to expansion/contraction from the reflected light measurement, thus evaluating the expansion/contraction properties of the material.

In one embodiment, the apparatus comprises an ellipsometer. In one embodiment, the ellipsometer is a null ellipsometer, a lock-in ellipsometer or a combination thereof.

In one embodiment, the means for extracting expansion/contraction parameters comprises a computer program, an algorithm, software or a combination thereof.

In one embodiment, this invention provides a process of preparing a device for the measurement of expansion/contraction properties of a material, the process comprising:
providing a sample comprising the material, the sample comprising a first surface and a second surface;
attaching a first substrate to the first surface of the sample;
attaching a second substrate to the second surface of the sample;
attaching a reflective material to the second substrate.

In one embodiment, the process further comprises applying an adhesive material to the second substrate such that the reflective material is attached to the second substrate via the adhesive material. In one embodiment, the process further comprises applying a first electrical contact to the first surface and a second electrical contact to the second surface of the first sample. In one embodiment, the second substrate functions also as the reflective material. According to this aspect and in one embodiment, the step of attaching a reflecting material to the second substrate is omitted.

In one embodiment, this invention provides a process of preparing a device for the measurement of expansion/contraction properties of a material, the process comprising:
providing a first sample comprising a material, the sample comprising a first surface and a second surface;
attaching a first substrate to the first surface of the first sample;
attaching a second substrate to the second surface of the first sample;
providing a second sample comprising a material, the sample comprising a first surface and a second surface;
attaching the second sample to the second substrate;
attaching a third substrate to the second surface of the second sample;
attaching a reflective material to the third substrate.

In one embodiment, the third substrate functions also as the reflective material. According to this aspect and in one embodiment, the step of attaching a reflecting material to the third substrate is omitted.

In one embodiment, the process further comprises applying a first electrical contact to said first surface and a second electrical contact to the second surface of the first sample, and applying a third electrical contact to the first surface and a fourth electrical contact to the second surface of the second sample. In one embodiment, the process further comprises applying an adhesive material to the third substrate such that the reflective material is attached to the third substrate via the adhesive material. In some embodiments, the third substrate is sufficiently flat and polished and it acts as the reflective material.

In one embodiment, in processes of this invention, the adhesive is modeling clay.

In one embodiment, in processes of this invention, the reflective material comprises an optical flat, SiO₂ or Si with flatness of λ/10. In one embodiment, the reflective material is reflective for the wavelength used to illuminate the reflective material.

In one embodiment, in processes of this invention, applying of the electrical contacts is conducted by pasting (e.g. pasting a silver paint).

In one embodiment, in processes of this invention, applying the adhesive is conducted by a method selected from pasting, contacting, pressing, gluing, spin-coating, drop-coating, or brushing of the adhesive to/onto the substrate.

In one embodiment, in processes of this invention, applying the reflective material is conducted by contacting the reflective material with the adhesive, or contacting the reflective material directly with the substrate.

In one embodiment, in processes of this invention, the order of the process steps is switched, such that each attachment step can be conducted prior to or following any other attachment step. For example, attaching the substrate to a second sample can be conducted prior to attachment of substrate(s) to a first sample. Attachment of the reflective material to a substrate can be performed before or after any step of sample-substrate attachment. Attachment of any substrate can be done prior to or following the attachment of any other substrate to any of the first or second samples. Application of adhesive can be done before or after other process steps, application of electrical contacts to any substrate/sample can be performed prior to or following any other process step as known to any person of ordinary skill in the art. In embodiments of device preparation, wherein the process further comprises applying a first electrical contact to the first surface and a second electrical contact to the second surface of any sample, the electrical contacts can be applied to the sample itself in one embodiment, and/or to the surface(s) of the substrate(s) that are brought into contact with the sample in some embodiments.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1C: (FIG. 1A) Scheme of the Lock-in ellipsometry set with an electromechanically active sample. (FIG. 1B) Measurement done on ceramic PZT pellets (P-51) showing linear dependence on the applied voltage (horizontal steps=U_{AC} [V]; squares=Reading [pA]), (FIG. 1C) the wide range of frequencies at which the signal could be measured (upper curve=reading [pA]; lower curve=Phi[°], the phase shift of the response).

FIGS. 2A-2B: (FIG. 2A) The sample structure of individual sample experiment; and (FIG. 2B) comparative experiment.

FIGS. 3A-3C: (FIG. 3A) Using optical flat as reflecting surface (instead of Si wafer), (FIG. 3B) the signal's amplitude was reduced, yet the signal to noise had improved (horizontal steps=U_{AC} [V]; squares=Reading [pA]). (FIG. 3C) The amplitude's stability over a wide range of frequencies had also been improved (upper curve=reading [pA]; lower curve=Phi[°], the phase shift of the response).

FIGS. 4A-4C: The optical response from a single crystal LiTaO₃; (FIG. 4A) linearly dependent on the applied voltage, (FIG. 4B) The dependence of the optical response on the frequency of the applied voltage over a wide frequency range (lower curve=reading [pA]; upper curve=Phi[°], the phase shift of the response). (FIG. 4C) The optical response from a ceramic pellet of GDC5 a showing quadratic dependence on the applied voltage.

FIGS. 5A-5D: The optical response from two PZT samples (an optical flat as reflective surface); (FIG. 5A) The door (arm) apparatus, implemented in order to collect only the vibration of each sample along the Z direction and translate it to oscillations in the degree at which the door is open. (FIG. 5B) The response of the top and the bottom PZTs (U_{AC}=6V at 471 Hz, measured at angles of incidence 50°, 56°, 60°, 70°, 80°). (FIG. 5C) The ration between the response of the top and the bottom PZTs is 1.74±0.21. (FIG. 5D) The dependence of the response of the top PZT on the frequency of the applied voltage over a wide frequency range (lower curve=reading [pA]; upper curve=Phi[°], the phase shift of the response).

FIG. 6: Schematic of optical measurement of electro-mechanical effect (or other effects) using a revised ‘door’ apparatus with two optional configurations, ‘on pivot’ reflection or ‘off pivot’ reflection (the off pivot is the option used for all the “door” apparatus examples described herein below). In both cases a silicon wafer was used as a reflective surface.

FIGS. 7A-7B: (FIG. 7A) The response of a PZT sample (the top sample in a set of two, glued one on top of the other, separated by an alumina plate) as function of the applied voltage (471 Hz, measured at several angles of incidence ranging from 50° to 80°, using a silicon wafer as a reflective surface). (FIG. 7B) The slope of the response to the applied voltage for the two PZT samples, as function of the angle of incidence, showing a peak in sensitivity at about 75°, due to the optical properties of the silicon.

FIGS. 8A-8C: An example of a comparative measurement conducted on commercially available samples—PZT (piezoelectric) on PMN-PT (electrostrictive). (FIG. 8A) The door apparatus mounted with the samples; (FIG. 8B) The parabola shaped curve as expected from an electrostrictive material as the optical response resulting from the applied voltage; (FIG. 8C) the linear dependence of the optical response on the applied voltage for the piezoelectric sample.

FIGS. 9A-9C: comparative measurements conducted on two commercially available electrostrictive samples (PMN-PT) using the door apparatus; FIG. 9A—response as function of applied AC voltage showing the parabola shaped curve as expected from an electrostrictive material; FIG. 9B—response as function of the applied AC voltage, showing the similar ratio between the response from the two samples—two sets of measurements were conducted while switching only the spring which is attached to the door, the set to the left showing the result obtained using a weak spring, the set to the right showing the result obtained using a strong spring, giving the versatility with regards to desired requirement—either measuring at the true ratio of the signals between the two samples or increased sensitivity to the top sample, in both cases the ratio was independent on the amplitude of the applied voltage; FIG. 9C, schematic of the device, left=weak spring; right=strong spring.

FIG. 10: Frequency sweep conducted for PMN-PT electrostrictive material, showing the wide frequency range at which the measurement can be conducted; in the measurement the system resonance peaks can clearly be observed.

FIGS. 11A-11C: (FIG. 11A) An example of a measurement done on a simplified version of the optical setup; in this case, a separate ellipsometer was used while its quarter wave plate had been removed. The sample that was measured was a piezoelectric sample (PZT) using the door apparatus. This aspect shows that while there is some reduction in sensitivity, it might be advantageous to build the simpler optical setup for even more robustness and reduced production costs; (FIG. 11B) The optical signal shows a clear linear dependence on the applied voltage, as expected from piezoelectric sample, (FIG. 11C) the phase of the optical signal is almost independent on the applied voltage.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The null ellipsometer is known from the late 19^{th} century for its sensitivity with respect to refractive indices and thicknesses of film stacks. Since then, the null ellipsometer was modified both equipment wise and methodology wise to enable it to monitor several electro-optic effects.

It was found that the null ellipsometer is sensitive also to minute vibrations of a reflection plain. This sensitivity originates from imperfection of the light source, laser beam divergence. For example, a reflective surface (such as Si wafer or SiO₂ optical flat, λ/10) was mounted on an electro-mechanically active sample so that only displacement could be transferred to the reflecting surface. Vibrations as small as 20 pm, produced a detectable optical response at the frequency of the vibration. This response scales linearly with the amplitude of the vibration.

This finding lead to a prospect that haven't been explored yet in the field of ellipsometry. According to results demonstrated herein below, the sensitivity, the applicability in an extremely wide frequency range and the ease of handling with respect to commonly used interferometry, makes the null ellipsometer with lock-in detection a good alternative to most sensitive modern interferometers.

### Theoretical Background

In one embodiment, this invention provides a device, method and apparatus for the measurement of expansion/contraction of materials. In some embodiments, such expansion/contraction is the result of electro-mechanic effects or of thermal expansion. In one embodiment, this invention provides a method for the measurements of electro-mechanical properties of a material. In one embodiment, the invention provides a method for the measurements of piezo-electric materials.

In one embodiment, the measurement setup uses He—Ne laser as its light source (JDSU 1125P). Although using such sources has many advantages when used for conventional ellipsometry measurements (focused, stable, coherent and mono-chromatic), there are also difficulties associated with such use, originating from known imperfections of the laser beam. One such obstacle is beam divergence, namely, the angle at which the diameter of the beam increases as the beam propagates.

In conventional ellipsometry measurements this affect may hinder the measurement and introduce complication in result interpretation.

In contrast, methods of this invention, take advantage of this effect. In embodiments of methods of this invention, such beam property is utilized as follows:

a material sample comprising expansion/contraction properties is covered by a reflective material. Polarized light illuminates the reflective material and is reflected from the reflective material and collected by a detector.

An expansion/contraction change is imposed on the sample, for example by applying a voltage to an electro-mechanical active sample or by changing the temperature of a thermal expansion active sample.
In response to the voltage applied or the temperature change, the sample experiences expansion/contraction. The movement associated with sample expansion/contraction is transferred to the reflecting material that is attached or connected to the sample. The reflecting surface thus experiences a displacement (both spatial and angular in some embodiments). This displacement alters the optical path of the beam, causing for minute beam defocusing, due to the beam divergence. The angle of incidence of the polarized light is changed consequently, thus changing the direction and polarization of the reflected beam. This change is read by the detector and is used to evaluate the expansion/contraction properties of the sample. As noted above, the polarized light does not reach the material itself. The polarized light solely illuminates and reflected off the reflective material that is attached/connected to the sample under test.
Embodiments of the present invention take advantage of these effects and the measured signal in methods of this invention is a result of the effects described herein above. Due to the fact that in conventional null-ellipsometry, movement of the sample is highly undesirable, the standard ellipsometry calculation does not take into account the beam divergence. As such, there is no literature data mentioning this sensitivity.

### Devices and Systems of the Invention

In one embodiment, this invention provides a novel device for the measurements of expansion/contraction properties of materials. Novel devices of this invention are constructed for optical measurements, in a way that the light used for measuring the sample, does not interact with the tested material itself. Devices of this invention comprise a sample of a material that is at least partially covered by a reflective material. The light used to measure the properties of the material, illuminates the reflective material and is reflected from the reflective material to a detector. In this way, displacement of the reflective material caused by expansion/contraction of the sample is sensed by the detection light. Since the light does not reach the sample, light-material interactions are eliminated and accordingly, such interactions do not interfere with the displacement measurement.

In one embodiment, this invention provides a device for the measurement of expansion/contraction properties of a material, the device comprising:
a sample comprising the material, the sample comprising a first surface and a second surface;
a first substrate and a second substrate, connected to the first surface and to the second surface of the sample respectively;
a reflective material attached to the second substrate.

In one embodiment, the device further comprises an adhesive in contact with the second substrate and in contact with the reflective material such that the reflective material is attached to the substrate via the adhesive material.

In one embodiment, the device further comprises two electrical contacts, each independently is in contact with the sample. In one embodiment, the device further comprises a heating source for heating the sample.

In one embodiment, the material possesses piezoelectric properties, electrostriction properties, thermal expansion properties or a combination thereof. In one embodiment, the heating source comprises IR laser. In one embodiment, the reflective material is reflective at a certain wavelength. In one embodiment, the wavelength is 632.8 nm.

In one embodiment, the thickness of the sample ranges between 1 nanometer to 100 millimeters. In one embodiment, the thickness of the substrate ranges between 10 micrometer to 100 millimeter, or between a few micrometers and 100 millimeter or between 1 micrometer and 100 millimeters. In one embodiment, the thickness of the adhesive ranges between from 1 nanometer to 1 millimeter. In one embodiment, the thickness of the reflective material ranges between from 1 micrometer to 100 millimeter. In one embodiment, the thickness of the reflective material ranges between from 275 micrometer to 50 millimeter. According to this aspect and in one embodiment, the second substrate is sufficiently flat and polished and it acts as the reflective material. Accordingly, in some embodiments, at least one of the substrates is a reflective material, and no additional reflective material is needed for devices and methods of this invention. In one embodiment, the thickness of the electrical contacts ranges between from 1 nanometer to 10 millimeters.

In one embodiment, the reflective material is attached to the substrate via the adhesive material. In one embodiment, the adhesive material comprises modeling clay. In one embodiment, the first substrate, second substrate or a combination thereof comprises alumina.

In one embodiment, the electrical contacts comprise Ag, Au, Cu, Pd, Pt, Sn or a combination thereof. In one embodiment, the electrical contacts comprise conductive paint such as silver paint.

In one embodiment, this invention provides a novel device for comparative measurements of expansion/contraction properties of materials. As described above, novel devices of this invention are constructed for optical measurements, wherein the light used for measuring the sample, does not interact with the material itself. In one embodiment, devices of this invention comprise two samples. One sample having known expansion/contraction properties (e.g. a known piezo-electric coefficient). Another sample comprises a material with unknown expansion/contraction properties (e.g. unknown piezo-electric coefficient). The two samples are mounted one on top of the other, and the top most sample is at least partially covered by a reflective material (see FIG. 2B). In some embodiments, spacers are inserted in between the two samples. The light used to measure the properties of the material, illuminates the reflective material and is reflected from the reflective material to a detector. In order to compare between the two samples, expansion/contraction is induced to one of the samples (e.g. by applying a voltage or by heating the sample) and an optical measurement is conducted as described above. Following this first measurement, expansion/contraction is induced to the second sample and an optical measurement is conducted as described above. The displacement pattern of the reflective material caused by expansion/contraction of the tested, unknown sample is sensed by the detection light and is compared to the displacement pattern of the known sample. Expansion/contraction parameters of the tested, unknown sample are thus evaluated. Since the light does not reach the sample, light-material interactions are eliminated and accordingly, such interactions do not interfere with the displacement measurement.

In one embodiment, prior to a comparative measurements wherein one sample comprises unknown material and another sample comprises a known material, a calibration measurement is conducted as follows:

Two samples with known properties are mounted one on top of the other in a device as described herein above (see FIG. 2B). The expansion/contraction properties of each of these known samples are measured, and the two measurements are compared. In this way, results variations that are associated with the position of the sample (e.g. top sample vs. bottom sample) are evaluated. When the unknown sample is measured, any variations that are attributed to sample position can be deducted from the results for better accuracy. An example for such measurement and calculation are presented in Example 4 herein below for an apparatus comprising a movable arm.

In one embodiment, this invention provides a device for the measurement of expansion/contraction properties of a material, the device comprising:
a first sample comprising a first material, the sample comprising a first surface and a second surface;
a first substrate and a second substrate, connected to the first surface and to the second surface of the sample respectively;
a second sample comprising a second material in contact with the second substrate;
a third substrate connected to the second sample;
a reflective material in contact with the third substrate.

In one embodiment, the device further comprises an adhesive in contact with the third substrate and in contact with the reflective material such that the reflective material is attached to the third substrate via the adhesive material. In one embodiment, the device further comprises a first set of two electrical contacts each independently is in contact with the first sample and a second set of two electrical contacts each independently is in contact with the second sample. In one embodiment, the device further comprises a heating source for heating the first sample, the second sample or a combination thereof.

In one embodiment, one of the first material and the second material possesses known expansion/contraction properties and another of the first material and the second material possesses un-known expansion/contraction properties.

In one embodiment, the first material and the second material possess piezoelectric properties, electrostriction properties, thermal expansion properties or a combination thereof.

In one embodiment, the heating source comprises IR laser.

In one embodiment, the reflective material is reflective at a certain wavelength. In one embodiment, the wavelength is 632.8 nm.

In one embodiment, the thickness of the sample ranges between 1 nanometer to 100 millimeters. In one embodiment, the thickness of the substrate ranges between 1 micrometer to 100 millimeter or between 10 micrometer and 100 millimeters. In one embodiment, the thickness of the adhesive ranges between from 1 nanometer to 1 millimeter. In one embodiment, the thickness of the reflective material ranges between from 1 micrometer to 100 millimeter. In one embodiment, the thickness of the electrical contacts ranges between from 1 nanometer to 10 millimeters.

In one embodiment, the reflective material is attached to the substrate via the adhesive material. In one embodiment, the adhesive material comprises modeling clay. In one embodiment, the first substrate, second substrate, third substrate or a combination thereof comprises alumina. In one embodiment, the electrical contacts comprise Ag, Au, Cu, Pd, Pt, Sn or a combination thereof. In one embodiment, the electrical contacts comprise conductive paint such as silver paint.

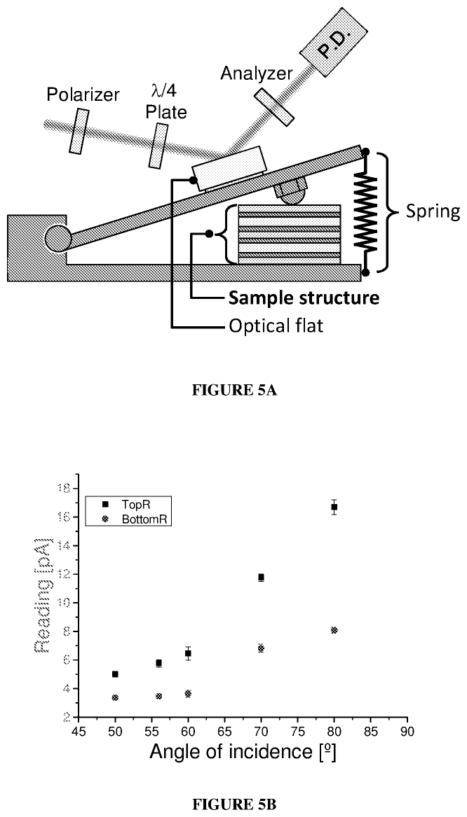

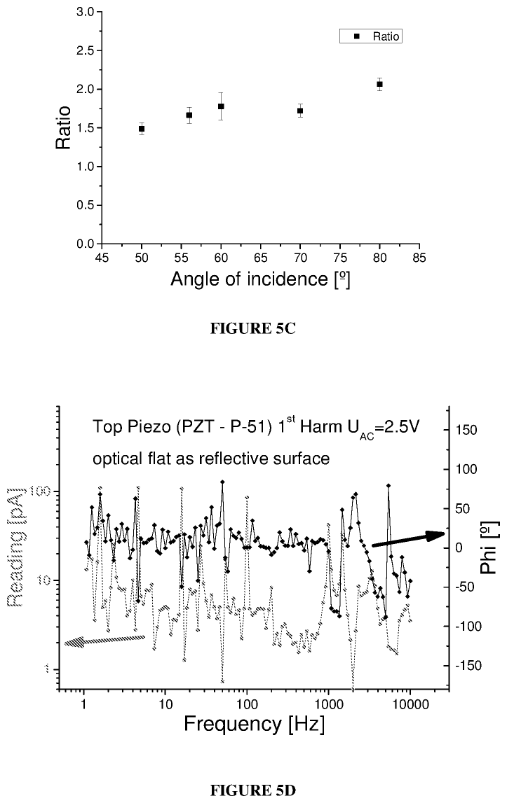

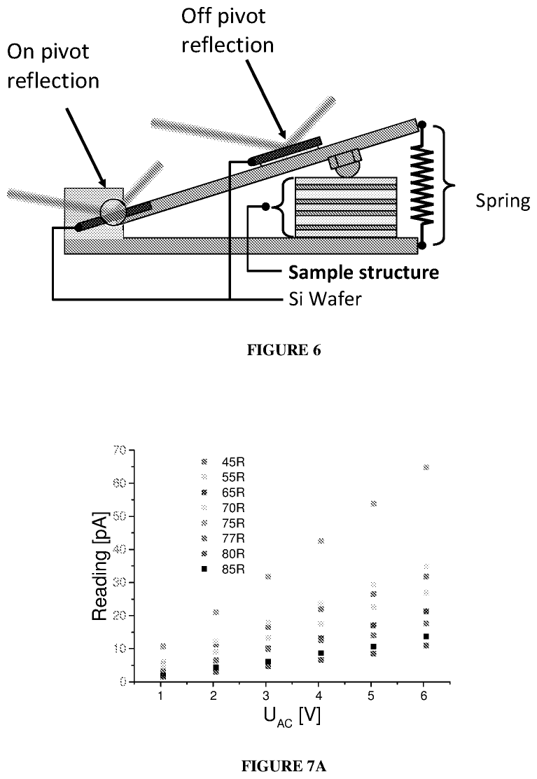

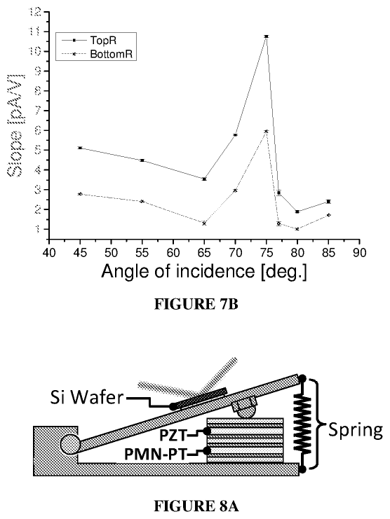

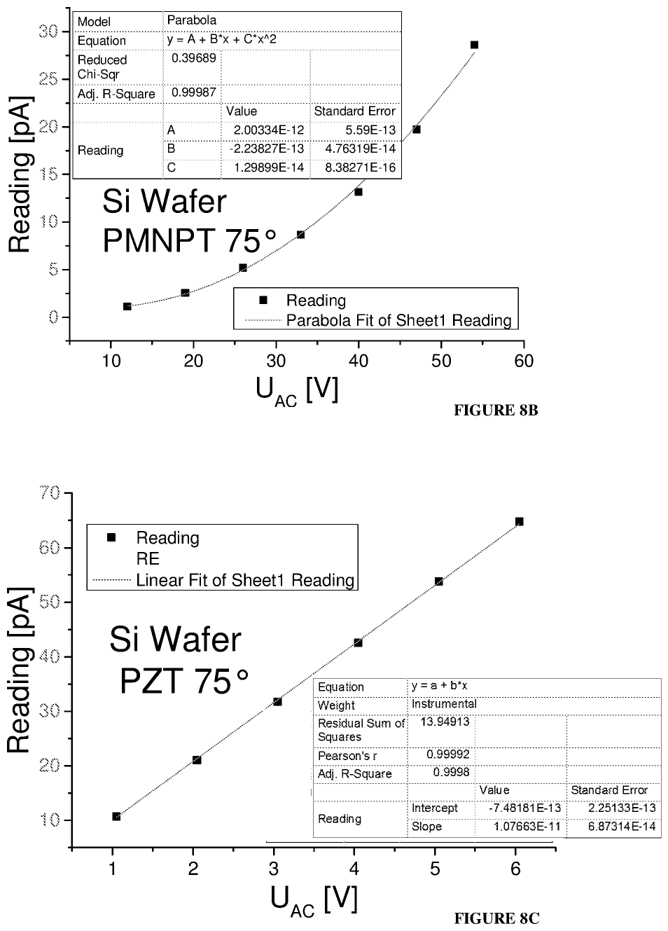

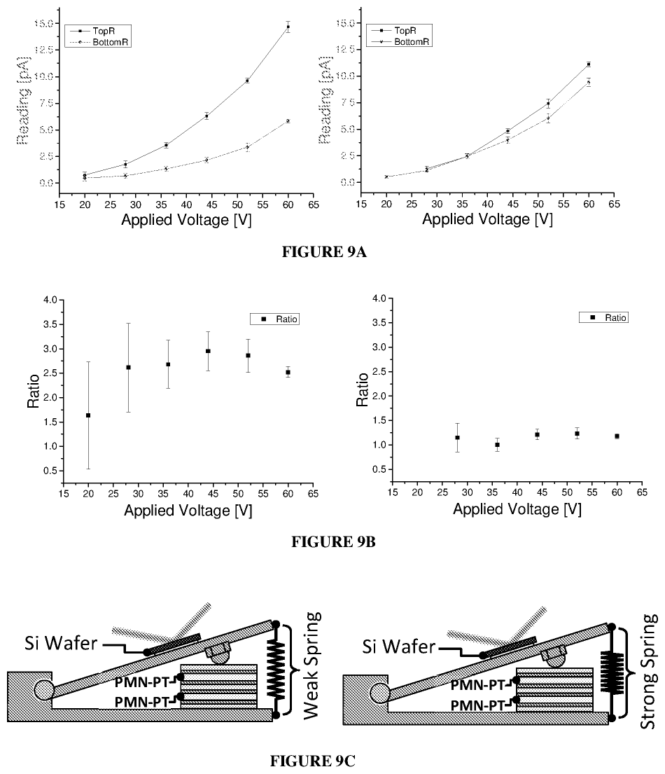

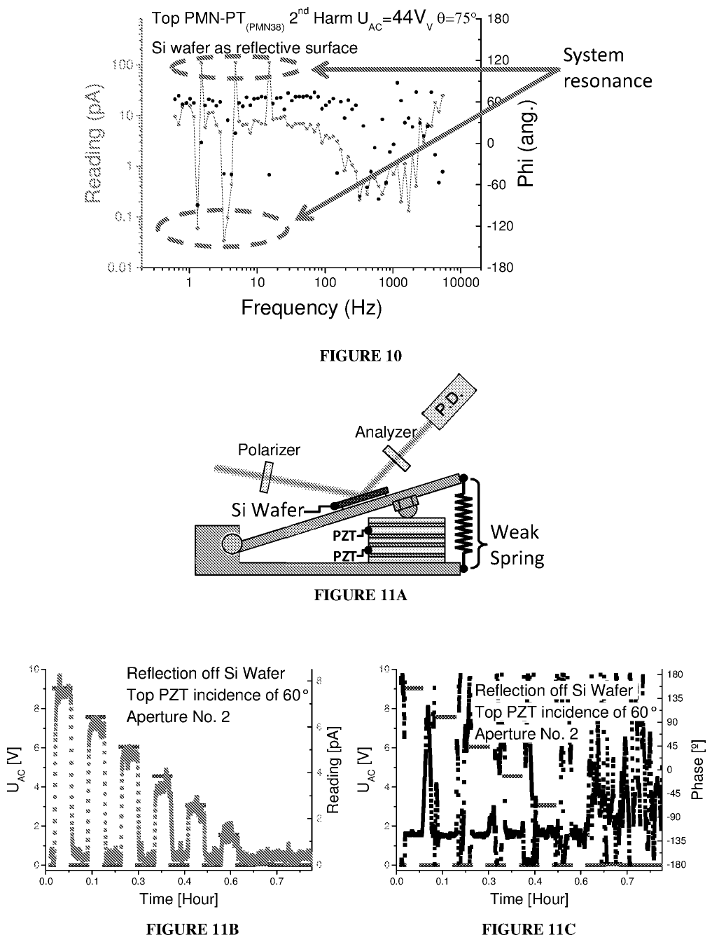

In one embodiment, the novel devices for comparative measurements described herein above (but without necessity for the reflective material that is connected to a substrate), further comprise a movable “arm”, such that the device is mounted under the movable arm. According to this aspect the arm is connected to a spring that controls the arm movement. An embodiment of such device is depicted in FIG. 5A. The arm is also referred to as a “door” in some embodiments. Two samples, one of known properties and the other of unknown properties are mounted in a comparative device as described above and as shown in FIG. 5A. A reflective material is applied to the upper portion of the arm as shown in FIG. 5A. The reflective material can be an optical flat in one embodiment. During measurement, expansion/contraction of the sample causes movement of the arm, and this movement affects the polarized light that illuminates the reflective material. As a result, the polarization of the light is changed, and this change is detected by a detector. In some embodiments, the top substrate in devices used with the ‘arm’ apparatus, is in contact with the arm or with a component that is connected to the arm as shown in FIG. 5A.

Using this set-up, factors other than vertical displacement that could interfere with the measurements are eliminated. For example sheer and rotation components in addition to non-uniformities in the samples are eliminated using this set-up.

According to this aspect and in one embodiment, this invention provides a system for the measurement of expansion/contraction properties of a material, the system comprising:
a device comprising:
   a sample comprising the material, the sample comprising a first surface and a second surface;
   a first substrate and a second substrate, connected to the first surface and to the second surface of the sample respectively;
   optionally two electrical contacts, each independently is in contact with the sample;
   optionally a heating source for heating the sample;
or:
a device comprising:
   a first sample comprising a first material, the sample comprising a first surface and a second surface;
   a first substrate and a second substrate, connected to the first surface and to the second surface of the sample respectively;
   a second sample comprising a second material in contact with the second substrate;
   a third substrate connected to the second sample;
   optionally, a first set of two electrical contacts each independently is in contact with the first sample and a second set of two electrical contacts each independently is in contact with the second sample;
   optionally a heating source for heating the first sample, the second sample or a combination thereof;
a base;
a movable arm comprising a first and a second end;
a spring;
a reflective material attached to the top surface of the arm;
   wherein the first end of the movable arm is associated with the base; the second end (or a second portion) of the movable arm is associated with the spring; the spring is attached to the base; and the device is located on top of the base and under the movable arm. In some embodiments, the top substrate is in contact with the arm or with a component that is contacted to the arm.

### Materials

In one embodiment, methods and apparatuses of this invention are applicable to all materials that exhibit contraction/expansion. In one embodiment, methods and apparatuses of this invention are applicable to all materials that exhibit electromechanical effects. In one embodiment, methods and apparatuses of this invention are applicable to all materials that exhibit thermal expansion. Any type of electro-mechanical effect or thermal expansion can be measured by methods and apparatuses of this invention. In one embodiment, samples of this invention comprise materials possessing piezo-electric properties. In one embodiment, the materials are piezo-electric materials. In one embodiment, piezo-electric materials of this invention comprise, lithium tantalate, lithium niobate, PZT (lead zirconate titanate), SiO₂ (quartz), thermally grown SiO₂.

In one embodiment, samples of this invention comprise materials possessing electrostrictive properties. In one embodiment, the materials are electrostrictive materials. In one embodiment, electrostrictive materials of this invention comprise strontium tantalate, PMN-PT (lead magnesium niobate-lead titanate), GDC (gadolinium doped ceria).

In one embodiment, the electrical contacts comprise silver paint, Au, Ag, Cu, Pd, Pt, Sn or a combination thereof. In one embodiment, any material can be used for the electrical contacts, as long as it is minimally affected by the mechanical strain developed by e.g. the electro-mechanic effect.

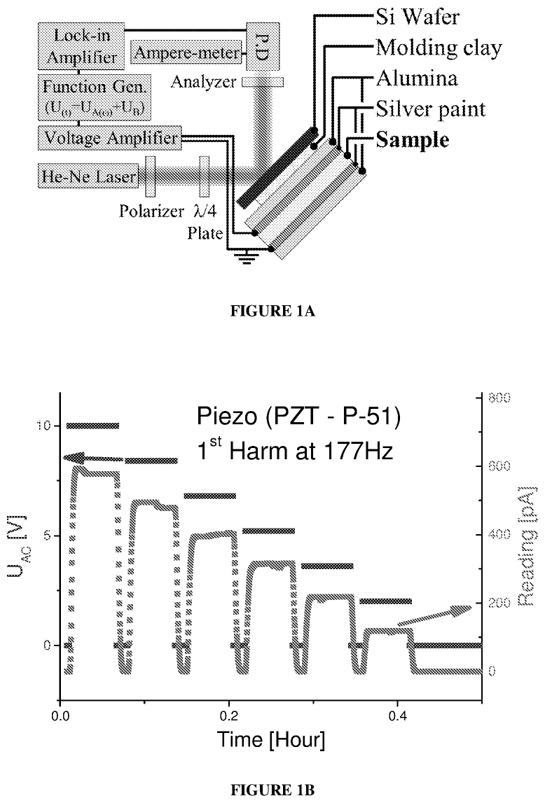

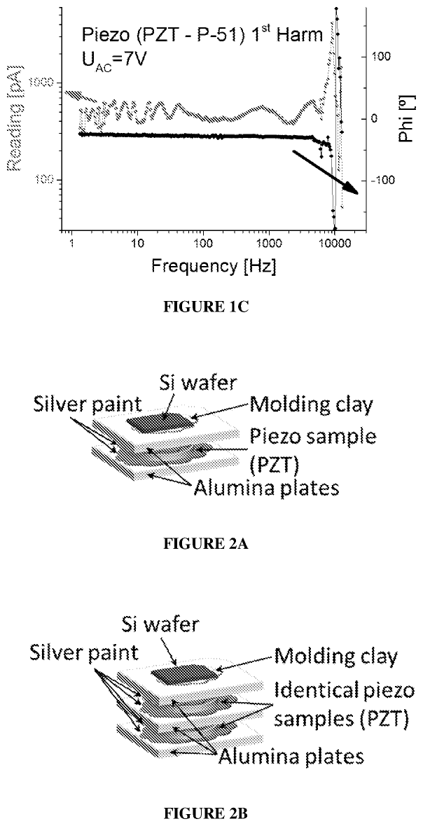

In one embodiment, the sample and the electrical contacts are sandwiched between two substrates as depicted e.g. in FIG. 1A. In one embodiment, the substrates comprise or consist of alumina. In one embodiment, the material used as a substrate is a solid hard material. In one embodiment, the material used as a substrate, is any material as long as it is minimally affected by the mechanical strain developed from the e.g. electro-mechanic effect. Accordingly, the substrate passes the spatial displacement and does not pass indirect effects such as bending, twisting or expansion/contraction perpendicular to the displacement. In one embodiment, the sample is glued to the substrate using silver paint. Other methods and materials for contacting the sample and the substrate are used in embodiments of this invention, as known to any person of ordinary skill in the art.

In one embodiment, the device comprises an adhesive for contacting the substrate to the reflecting material. In one embodiment, when applied to the substrate/reflective material, the adhesive is in a liquid form, or in a gel form or in the form of a viscous fluid. Such adhesive is used to glue the substrate to the reflective material. In one embodiment, once the glue is brought into contact with the substrate and with the reflective material, the glue is left to dry and solidify. Accordingly, when the device is mounted for detection, the glue is in a solid form. In one embodiment, the adhesive comprises glue, clay, dough, modeling clay such as plasticine or plastilina, polymer, or a combination thereof. In one embodiment, the adhesive comprises an adhesive tape, a double-sided adhesive tape. In one embodiment, the requirement for the adhesive material is that during measurement it will be minimally affected or not affected by the mechanical strain developed by the electro-mechanic effect of the sample. Therefore, such adhesive passes the spatial displacement and does not absorb the effect of the movement (unlike gels and rubbers that would act as vibration dampers).

In one embodiment, the device comprises a reflective material. In one embodiment, the reflective material is reflective at a certain wavelength. In one embodiment, the reflective material is reflective at the wavelength of the light source used in the ellipsometer apparatus of this invention. In one embodiment, the reflective material is reflective over a certain range of wavelengths. In one embodiment, the reflective material is reflective at a wavelength of 632.8 nm. In one embodiment, the reflective material comprises a Si wafer. In one embodiment, the reflective material comprises an optical flat. In one embodiment, the reflective material is any flat reflective material. In one embodiment, the reflective material is preferably a reflective material with minimal extinction coefficient.

### Geometry

In one embodiment, the sample, the substrate(s) and the reflective materials are each in the form of a thin piece/part comprising two macroscopically flat large surfaces and an edge or edges. In one embodiment, in devices of the invention, the thin parts are arranged in a layered structure wherein each part forms a layer as described e.g. in FIG. 1A. In one embodiment, the large surfaces of the sample/substrates are in contact with other elements (layers) of the device. In one embodiment, the two surfaces are perpendicular to the direction of stacking of the layers of the device. In one embodiment the arrangement of the sample and the substrates is described in FIG. 1A. It can be seen that the two large surfaces of the sample and the two large surfaces of the substrates are perpendicular to the virtual line going through the stack of device substrates/sample components/elements.

### Elements, Dimensions and Values

In one embodiment, the thickness of the sample ranges between 1 nanometer to tens of millimeters. In one embodiment, the thickness of the electrical contacts ranges from nanometers to a few millimeters. In one embodiment, the thickness of the reflective material ranges from micrometers to tens of millimeters. In one embodiment, the only requirement for the reflective material is to have reflective surface. According to this aspect and in one embodiment, the thickness of the reflective material is not relevant to its function. Therefore, the reflective material can be of any thickness, as long as it has a reflective surface. In one embodiment, the thickness of the substrates ranges between from tens or hundreds of micrometers to tens of millimeters. In one embodiment, the only requirement of the substrate is to avoid the transfer of mechanical strain/prevent from bending. According to this aspect and in one embodiment, the thickness of the substrate is not relevant to its function. Therefore, the substrate can have any thickness, as long as it performs its function. In one embodiment, the thickness of the adhesive ranges between one or a few nanometers to a few hundreds of micrometers.

In one embodiment, the thickness of each element from the elements described herein above can assume any value appropriate for measurement.

In one embodiment, the reflective surface is illuminated by a light source with a wavelength of 632.8 nm. In one embodiment, the light source is a laser. In one embodiment, the laser is a He—Ne laser. In one embodiment, the wavelength used is a wavelength compatible with the optical elements of the ellipsometer, (e.g. 632.8 nm). In one embodiment, the source is a light emitting diode (LED). In one embodiment, the source wavelength is selected from 465 nm, 525 nm, 580 nm, 635 nm. Different systems using different wave lengths can be used in embodiments of this invention. Any wavelength can be used as long as the ellipsometer's optical elements are compatible with it. Many other types of lasers and other light sources can be used in embodiments of the invention as known to the skilled artisan.

The light illuminating the surface is reflected off the surface. The light reflected off the surface of the reflective material passes through an analyzer and reaches a detector as shown in FIG. 1A. In one embodiment, the detector for reflected light comprises a photodiode (P.D. in FIG. 1A). Lock-in amplification is needed in order to detect a measurable signal.

In one embodiment, the device further comprises a control sample. In one embodiment the control sample is a sample with known contraction/expansion property. In one embodiment the control sample is a sample with a known electro-mechanical property. For example, the control sample comprises a material with a known piezo-electric coefficient. The measured signal from the control sample is compared to the measured signal from a tested sample in one embodiment, thus extracting contraction/expansion parameters such as electro-mechanical properties for the sample to be tested.

### Methods of the Invention

In one embodiment, this invention provides a method of measuring expansion/contraction properties of a material, the method comprising:
providing a device comprising:
   a sample comprising the material, the sample comprising a first surface and a second surface;
   a first substrate and a second substrate, connected to the first surface and to the second surface of the sample respectively;
   a reflective material attached to the second substrate;
   optionally two electrical contacts, each independently is in contact with the sample;
   optionally a heating source for heating the sample;
optionally applying voltage to the sample using the electrical contacts;
optionally heating the sample;
illuminating the reflective material using a light source, such that said illumination comprises light having known and controllable polarization;
collecting light reflected off the reflective material;
measuring amplitude and phase of the oscillating change in polarization of the reflected light;
extracting parameters related to expansion/contraction from the reflected light measurement, thus evaluating the expansion/contraction properties of the material.

In one embodiment, the device further comprises an adhesive in contact with the second substrate and in contact with the reflective material such that the reflective material is attached to the second substrate via the adhesive material.

In one embodiment, the light source is a He—Ne laser. In one embodiment, collecting the reflected light is done using a detector. In one embodiment the method allows qualitative evaluation of the expansion/contraction properties.

In one embodiment, this invention provides a method of measuring expansion/contraction properties of a material, the method comprising:
providing a device comprising:
   a first sample comprising a first material, the sample comprising a first surface and a second surface;
   a first substrate and a second substrate, connected to the first surface and to the second surface of the sample respectively;
   a second sample comprising a second material in contact with the second substrate;
   a third substrate connected to the second sample;
   a reflective material in contact with the third substrate;
   optionally, a first set of two electrical contacts each independently is in contact with the first sample and a second set of two electrical contacts each independently is in contact with the second sample;
   optionally a heating source for heating the first sample, the second sample or a combination thereof;
measuring the first sample, the measurement comprising:
   optionally applying voltage to the first sample using the electrical contacts;
   optionally heating the first sample using the heating source;
   illuminating the reflective material with a light source, such that said illumination comprises light having known and controllable polarization;
   collecting light reflected off the reflective material;
   measuring amplitude and phase of the oscillating change in polarization of the reflected light;
   extracting parameters related to expansion/contraction from the reflected light measurement, thus evaluating the expansion/contraction properties of the material.
measuring the second sample, said measurement comprising:
   optionally applying voltage to the second sample using the electrical contacts;
   optionally heating the second sample using the heating source;
   illuminating the reflective material with a light source;
   collecting light reflected off the reflective material;
   measuring amplitude and phase of the oscillating change in polarization of the reflected light;
   extracting parameters related to expansion/contraction from the reflected light measurement, thus evaluating the expansion/contraction properties of the material.
comparing parameters extracted from the first sample measurement to parameters extracted from the second sample measurement, thus evaluating the expansion/contraction properties of the first material, the second material or a combination thereof.

In one embodiment, the method further comprises an additional measurement of two identical samples of known materials placed one on top of the other in a device as described herein above. The purpose of such measurement is to evaluate the effect of the position (top/bottom) of the sample on the parameters extracted from its measurement. Such effect is taken into account when evaluating/calculating the parameters for an unknown sample as described herein above. Such additional measurement is performed before or after the measurement of the two different samples (first sample and second sample) in some embodiments.

In one embodiment, the device further comprises an adhesive in contact with the third substrate and in contact with the reflective material such that the reflective material is attached to the third substrate via the adhesive material.

In one embodiment, the step of measuring the second sample is conducted prior to the step of measuring the first sample.

In one embodiment, one of the first material and the second material possesses known expansion/contraction properties and another of the first material and the second material possesses un-known expansion/contraction properties. In one embodiment, the method allows quantitative evaluation of the expansion/contraction properties of the material. In one embodiment, the quantitative evaluation comprises evaluation of the piezo-electric coefficient or electrostriction coefficient of the material. Property evaluation is for the material that possesses unknown expansion/contraction properties in one embodiment.

In one embodiment, this invention provides a method of measuring expansion/contraction properties of a material, the method comprising:
providing a system comprising:
a device comprising:
   a sample comprising the material, the sample comprising a first surface and a second surface;
   a first substrate and a second substrate, connected to the first surface and to the second surface of the sample respectively;
   optionally two electrical contacts, each independently is in contact with the sample;
   optionally a heating source for heating the sample;
a base;
a movable arm comprising a first and a second end;
a spring;
a reflective material attached to the top surface of the arm;
   wherein the first end of the movable arm is associated with the base; the second end (or a portion close to the second end) of the movable arm is associated with the spring; the spring is attached to the base; and the device is located on top of the base and under the movable arm;
optionally applying voltage to the sample using the electrical contacts;
optionally heating the sample;
illuminating the reflective material with a light source;
collecting light reflected off the reflective material;
measuring amplitude and phase of the oscillating change in polarization of the reflected light;
extracting parameters related to expansion/contraction from the reflected light measurement, thus evaluating the expansion/contraction properties of the material.

In one embodiment, this invention provides a method of measuring expansion/contraction properties of a material, the method comprising:
providing a system comprising:
a device comprising:
   a first sample comprising a first material, the sample comprising a first surface and a second surface;
   a first substrate and a second substrate, connected to the first surface and to the second surface of the sample respectively;
   a second sample comprising a second material in contact with the second substrate;
   a third substrate connected to the second sample;
   optionally, a first set of two electrical contacts each independently is in contact with the first sample and a second set of two electrical contacts each independently is in contact with the second sample;
   optionally a heating source for heating the first sample, the second sample or a combination thereof;
a base;
a movable arm comprising a first end and a second end;
a spring;
a reflective material attached to the top surface of the arm;
   wherein said first end of the movable arm is associated with the base; the second end (or a portion close to the second end) of the movable arm is associated with the spring; the spring is attached to the base; and the device is located on top of the base and under the movable arm;

b. measuring the first sample, the measurement comprising:
optionally applying voltage to the first sample using the electrical contacts;
optionally heating the first sample using the heating source;
illuminating the reflective material with a light source;
collecting light reflected off the reflective material;
measuring amplitude and phase of the oscillating change in polarization of the reflected light;
extracting parameters related to expansion/contraction from the reflected light measurement, thus evaluating the expansion/contraction properties of the first material.

c. measuring the second sample, the measurement comprising:
optionally applying voltage to the second sample using the electrical contacts;
optionally heating the second sample using the heating source;
illuminating the reflective material with a light source;
collecting light reflected off the reflective material;
measuring amplitude and phase of the oscillating change in polarization of the reflected light;
extracting parameters related to expansion/contraction from the reflected light measurement, thus evaluating the expansion/contraction properties of the second material.
comparing parameters extracted from the first sample measurement to parameters extracted from the second sample measurement, thus evaluating the expansion/contraction properties of the first material, the second material or a combination thereof.

An embodiment of this method is presented in FIG. 5A. As can be seen from the figure, the samples/substrates are located on the base and beneath the movable arm. The sample structure (sample/substrates) is glued to the base in some embodiments, i.e. the first substrate is glued to the base. The reflective material is mounted on top of the movable arm such that the light illuminates the reflective material and is reflected from it. In some embodiments, an adhesive is used to attach the reflective material to the movable arm. According to this aspect and in one embodiment, devices of this invention further comprise an adhesive, in contact with the top side of the movable arm and in contact with the reflective material, such that the reflective material is attached to the arm via the adhesive material. In some embodiment, the top surface of the arm is reflective and is used as the reflective material. According to this aspect and in one embodiment, no additional reflective material is needed.

In one embodiment, the step of measuring the second sample is conducted prior to the step of measuring the first sample.

In one embodiment, one of the first material and the second material possesses known expansion/contraction properties and another of the first material and the second material possesses un-known expansion/contraction properties. In one embodiment, the method allows quantitative evaluation of the expansion/contraction properties of the first/second material. In one embodiment, the quantitative evaluation comprises evaluation of the piezo-electric coefficient or electrostriction coefficient of the material.

In one embodiment, methods of this invention comprise the use of an ellipsometer (or a similar optical system). In one embodiment, an ellipsometer is used as follows: a device is placed on the ellipsometer in one of two ways, either as in FIG. 1A or as in FIG. 5A. After the device is properly aligned, the polarizer and analyzer pair of the ellipsometer are brought to the angle at which the photo current produced by a photo diode (detector) is minimal—this process is referred to as “nulling”. Following the nulling process, the analyzer's angle is shifted in order to increase the sensitivity to polarization change of the reflected light. The detector measures the intensity of the light after passing through the analyzer, which is an indication of the polarization of the reflected light; namely changes in the intensity of the light detected by the detector correspond to changes in the polarization of the reflected light (light reflected off the reflecting material, e.g. the Si wafer shown in FIG. 1A).

In one embodiment, during the measurement of the device, a voltage source is used to apply voltage to the sample. Voltage is applied to the sample by connecting the voltage source to the two electrical contacts, one on each side of the sample as shown for example in FIG. 1A. The voltage source (function generator, voltage amplifier and/or other voltage source components/devices) supplies AC voltage or a combination of DC and AC voltages to the sample through the electrical contacts. The applied voltage causes vibrations of the sample that are passed on to the reflective surface. These vibrations affect the intensity of the light that is measured by the detector, because the vibration of the reflective surface changes the polarization of the reflected light. This effect is detected by the detector and amplified by the lock-in amplifier and can be used to interpret the electro-mechanical properties of the sample—that is, the amplitude of the change in the photo current generated by the photodiode is correlated to the amplitude of the sample vibrations. In some embodiments, a lock-in amplifier is used to enhance sensitivity of the detected signals. In other embodiments, a scope is used to record the change in intensity that is measured by the detector, at each cycle of the AC voltage. As such, in some embodiments, the scope is used in a similar way to the lock in amplifier and information on the desired sample is obtained.

In one embodiment, the description provided herein above describes the means for measuring amplitude and phase of the oscillating change in polarization of the reflected light in methods of this invention.

In one embodiment, methods of this invention utilize a control sample that is measured in order to better evaluate the parameters of a tested sample. In one embodiment, methods of this invention utilize a control sample that is measured in order to better evaluate the parameters of a sample that exhibits expansion/contraction properties. In one embodiment, methods of this invention utilize a control sample that is measured in order to better evaluate the parameters of a sample comprising a material that exhibits electromechanical effects or thermal expansion. In one embodiment, methods of this invention utilize a control sample that is measured in order to better evaluate the parameters of a piezo-electric sample.

In one embodiment, the control sample and the tested sample are measured consequently. In one embodiment, the control sample and the tested sample are mounted one on top of the other for the measurement as shown for example in FIG. 5A. In one embodiment the control sample comprises of a material with a known electromechanical or thermal expansion property. In one embodiment, the control sample comprises a material with known piezo-electric or electrostrictive parameters. It should be noted that methods, devices and apparatuses of this invention can be used to measure many types of mechanical effects and are not restricted to measurements of a piezo-electric or electrostrictive materials. In one embodiment, devices, methods and apparatuses of this invention are used to measure thermal expansion of a sample and other mechanical effects.

In one embodiment, methods, devices and apparatuses of this invention are used to investigate thermal expansion of materials. According to this aspect and in one embodiment, a material sample is heated periodically and the optical response is recorded according to the method described herein above (using an ellipsometer or a similar optical system). This optical response is compared to the response resulting from the periodic heating of a known sample. A thermal expansion coefficient is thus obtained.

### Apparatuses of the Invention

In one embodiment, this invention provides an apparatus for the measurement of expansion/contraction properties of a material, the apparatus comprising:
a first device or a second device, wherein:
   the first device comprising:
      a sample comprising the material, the sample comprising a first surface and a second surface;
      a first substrate and a second substrate, connected to the first surface and to the second surface of the sample respectively;
      an adhesive in contact with the second substrate;
      a reflective material in contact with the adhesive;
      optionally two electrical contacts, each independently is in contact with the sample;
      optionally a heating source for heating the sample;
   the second device comprising:
      a first sample comprising a first material, the sample comprising a first surface and a second surface;
      a first substrate and a second substrate, connected to the first surface and to the second surface of the sample respectively;
      a second sample comprising a second material in contact with the second substrate;
      a third substrate connected to the second sample;
      an adhesive in contact with the third substrate;
      a reflective material in contact with the adhesive;
      optionally, a first set of two electrical contacts each independently is in contact with the first sample and a second set of two electrical contacts each independently is in contact with the second sample;
      optionally a heating source for heating the first sample, the second sample or a combination thereof;
light source for illuminating the reflective material;
a first polarizer for polarizing the light;
optionally a quarter wave plate;
a second polarizer for polarizing light reflected off the reflective material;
detector for collecting light reflected off the reflective material;
optionally a power supply for applying voltage to the sample;
means for measuring amplitude and phase of the oscillating change in polarization of the reflected light;
means for extracting parameters related to expansion/contraction from the reflected light measurement, thus evaluating the expansion/contraction properties of the material.

In one embodiment, the apparatus comprises an ellipsometer. In one embodiment, the ellipsometer is a null ellipsometer, a lock-in ellipsometer or a combination thereof. In one embodiment, the means for extracting expansion/contraction parameters comprises a computer program, an algorithm, software or a combination thereof.

In one embodiment, apparatuses of this invention comprise an ellipsometer. In one embodiment, the ellipsometer comprises a light source, a detector, a polarizer and an analyzer and a quarter wave plate. In some embodiments, the ellipsometer is a null ellipsometer. In one embodiment, the ellipsometer is coupled to a lock-in amplifier and a function generator. The ellipsometer comprise a sample holder. In one embodiment, the sample holder is alignable. In one embodiment, the sample holder is movable for the purpose of alignment. In one embodiment, the sample holder is movable in a certain X-Y plane and in a Z direction perpendicular to that plane. In one embodiment, the sample holder is further movable (rotatable) at an angle(s) with respect to the X-Y plane. In one embodiment, the sample holder is stationary during measurement. In one embodiment, the sample holder is movable. In one embodiment, movement of the sample holder is used to place a certain measurable area under the incoming light beam. In one embodiment, the sample holder is static during the measurement but is adjustable for alignment of the sample/reflective surface prior to a measurement. In one embodiment, the ellipsometer further comprises a current meter, a voltage amplifier, other electrical components, electrical contacts/wires, computer or a combination thereof. In one embodiment, quarter wave plate is not used.

In one embodiment, apparatuses of this invention comprise a polarizer, an analyzer, a photo diode detector, other detectors, a voltage source, electrical contacts, function generator, voltage amplifier, other voltage source components/devices, lock-in amplifier, and/or other elements and components as known in the art.

In one embodiment, the apparatus further comprises an adhesive in contact with the second substrate of the first device or in contact with the third substrate of the second device and in contact with the reflective material such that the reflective material is attached to the second substrate or to the third substrate via the adhesive material. In one embodiment, the apparatus further comprising an adhesive in contact with the second substrate and in contact with the reflective material such that the reflective material is attached to the second substrate via the adhesive material. In one embodiment, the apparatus further comprising an adhesive in contact with the third substrate and in contact with the reflective material such that the reflective material is attached to the third substrate via the adhesive material. In one embodiment, the apparatus further comprising two electrical contacts, each independently is in contact with a sample. In one embodiment, a set of two electrical contacts is connected to each sample in devices comprising more than one sample. In one embodiment, the apparatus further comprising a heating source for heating the sample. In one embodiment, the heating source comprises IR laser. In one embodiment, the sample material possesses piezoelectric properties, electrostriction properties, thermal expansion properties or a combination thereof. In one embodiment, the reflective material is reflective at a certain wavelength. In one embodiment, the wavelength is 632.8 nm. In one embodiment, the thickness of the sample ranges between 1 nanometer to 100 millimeters. In one embodiment, the thickness of the substrate ranges between 1 micrometer to 100 millimeter or between 10 micrometers and 100 millimeters. In one embodiment, the thickness of said adhesive ranges between from 1 nanometer to 1 millimeter. In one embodiment, the thickness of said electrical contacts ranges between from 1 nanometer to 10 millimeters. In one embodiment, the adhesive material comprises modeling clay. In one embodiment, the first substrate, second substrate or a combination thereof comprises alumina. In one embodiment, the electrical contacts comprise Ag, Au, Cu, Pd, Pt, Sn or a combination thereof. In one embodiment, the electrical contacts comprise conductive paint such as silver paint.

In some embodiment, devices, systems and apparatuses of this invention further comprise heating-related elements such as heat isolation elements, heat sinks, thermometers, heat sources, heat-control elements, timers and other heat-related elements as known in the art.

### Processes for Producing Devices of the Invention

In one embodiment, this invention provides a process of preparing a device for the measurement of expansion/contraction properties of a material, the process comprising:
providing a sample comprising the material, the sample comprising a first surface and a second surface;
optionally applying a first electrical contact to the first surface and a second electrical contact to the second surface;
connecting a first substrate to the first surface of the sample, such that the first substrate is in contact with the first electrical contact, with the first surface, or with a combination thereof;
connecting a second substrate to the second surface of the sample, such that the second substrate is in contact with the second electrical contact, with the second surface, or with a combination thereof;
applying an adhesive material to the second substrate;
applying a reflective material to the adhesive material such that the reflective material is in contact with the adhesive material.

In one embodiment, this invention provides a process of preparing a device for the measurement of expansion/contraction properties of a material, the process comprising:
providing a first sample comprising a first material, the sample comprising a first surface and a second surface;
optionally applying a first electrical contact to the first surface and a second electrical contact to the second surface;
connecting a first substrate to the first surface of the sample, such that the first substrate is in contact with the first electrical contact, with the first surface, or with a combination thereof;
connecting a second substrate to the second surface of the sample, such that the second substrate is in contact with the second electrical contact, with the second surface, or with a combination thereof;
providing a second sample comprising a second material, the sample comprising a first surface and a second surface;
optionally applying a third electrical contact to the first surface and a fourth electrical contact to the second surface of the second sample;
connecting the second sample to the second substrate such that the second substrate is in contact with the third electrical contact, with the first surface of the second sample, or with a combination thereof;
connecting a third substrate to the second surface of the second sample, such that the second substrate is in contact with the fourth electrical contact, with the second surface of the second sample, or with a combination thereof;
applying an adhesive material to the third substrate;
applying a reflective material to the adhesive material such that the reflective material is in contact with the adhesive material.

In one embodiment, in processes of this invention, the adhesive is modeling clay. In one embodiment, the reflective material comprises an optical flat, SiO₂ or Si with flatness of λ/10. In one embodiment, applying of the electrical contacts is conducted by pasting. In one embodiment, applying the adhesive is conducted by pasting, contacting, pressing, gluing, said adhesive to/onto the sample. In one embodiment, applying the reflective material is conducted by contacting the reflective material with the adhesive. In one embodiment, the order of the process steps is switched/changed/varied. According to this aspect and in one embodiment, any attachment/contacting/connecting/pasting/applying step of one element to another can be performed prior to or following any other attachment/contacting/connecting/pasting/applying step of one element to another as known in the art.

In one embodiment, a process for producing devices of this invention involves the construction of a layered structure. According to this aspect and in one embodiment, a piece of sample comprising two opposing macroscopically-flat surfaces is attached to at least two electrical contacts such that one contact is attached to one surface and the other contact is attached to the other surface of the sample.

In one embodiment, this invention provides a process of preparing a system for the measurement of expansion/contraction properties of a material, wherein the system comprises one of the devices as described herein above and a construction for the device, the construction comprising a base, a movable arm, a spring and a reflective material. In one embodiment, processes for preparing a system of the invention comprise providing or forming a movable arm, attaching the arm to a base, attaching a spring to the arm and to the base, and placing and securing a device onto the base and underneath the arm. The order of the process steps can be varied, i.e. a certain process step can be performed prior to or following other process steps as known in the art. In one embodiment, the spring is attached to the arm at its end or close to its end. In one embodiment, the spring is attached to the arm at a portion of the arm close to the arm's end.

### Definitions

Molding clay is modeling clay, or clay or play dough, or dough. In some embodiment, any material possessing the mechanical properties of a modeling or molding clay can be used to attach the reflective material to a substrate or to other elements/components of this invention.

The reflective material is attached or connected to the sampled material. Attachment or connection can be direct or indirect. Indirect connection between the reflective material and the sample comprise other elements/components that are placed or positioned between the reflective material and the sample. For example, a substrate(s), electrical contacts, adhesive(s) or a combination thereof can be placed between the reflective material and the sample such that the reflective material is attached or connected to the sample through these elements.

In one embodiment, the sample comprises a material having expansion/contraction properties. In one embodiment, the sample consists of a material having expansion/contraction properties. In one embodiment, the sample is the material.

Apparatuses of this invention comprise an ellipsometer in one embodiment. Apparatuses of this invention comprise other optical systems in some embodiments. In some embodiments, apparatuses of this invention comprise optical systems that are similar to ellipsometers, but can vary from it by one or more components, can vary from it by the specifications of one or more components, by dimensions, by the functions encompassed by the system or by a combination thereof.

An analyzer is a polarizer, a second polarizer, the polarizer through which light is transferred after being reflected from the reflective surface.

A reflective/reflecting material comprises a reflective surface. Reflective material is referred to as reflective/reflecting surface in some embodiments.

In some embodiments, systems of this invention comprise or consist of apparatuses of the invention. In some embodiments, apparatuses of this invention comprise or consist of systems of the invention. Accordingly, elements described for apparatuses of this invention can be used in systems of this invention and elements described for systems of this invention can be used in apparatuses of this invention.

In some embodiments, properties of a certain sample are described. Such properties are applicable to other samples in embodiments of this invention. Similarly in some embodiments, the properties of a material present in one sample are applicable to materials present in other samples.

In some embodiments, more than two samples can be included and measured in devices of this invention.

In some embodiments, methods of the invention comprise the steps of optionally applying voltage to a sample using the electrical contacts and optionally heating a sample using a heating source. In some embodiments, applying a voltage to a sample is used to test the electromechanical effect of a sample (or of a material). In some embodiments, heating the sample is used to test the thermal expansion properties of a sample (or of a material). Each of these method steps can be conducted independently or in conjunction. In addition to heating the sample, the sample can also be cooled and the sample temperature can be controlled/kept constant at a certain value, as known in the art.

### Conclusion

The proposed technique was found to be applicable for investigation of electromechanical effects not only in the case of Pockels and Kerr effects, but also of the direct effects (piezo-electricity and electrostriction) by vibrating the reflecting surface that is (indirectly) glued to an electromechanically active sample as shown for example in FIG. 5A. The sensitivity of this new technique is comparable to extremely complex and expensive interferometers, more so, such interferometers do not support as wide frequency range as the proposed technique. The physical origin behind this technique had never been reported in the literature.

In one embodiment, the term “a” or “one” or “an” refers to at least one. In one embodiment the phrase “two or more” may be of any denomination, which will suit a particular purpose. In one embodiment, “about” or “approximately” may comprise a deviance from the indicated term of +1%, or in some embodiments, −1%, or in some embodiments, ±2.5%, or in some embodiments, ±5%, or in some embodiments, ±7.5%, or in some embodiments, ±10%, or in some embodiments, ±15%, or in some embodiments, ±20%, or in some embodiments, ±25%.

### EXAMPLES

### Example 1

### Sample Preparation

Electromechanically active samples were glued in between 0.5 mm thick alumina slides via silver paint. As a reflecting surface, two options were explored; cut Si wafers (University Wafers, <0.005 Ω·cm, [100] p-type boron) and a glass optical flat (Edmund Optics Inc., 25.4 mm Dia. 12.7 mm thick λ/10 Fused Silica Dual Surface Flat), each was glued to the top alumina slide by a modeling clay. This was done to insure no mechanical forces other than displacement are transferred to the reflecting surface. Therefore, none of the optical properties of the reflecting surface was prone to change during the measurement (FIG. 2A). Lastly, copper wires were connected to the bottom and top electrodes (the electrical contacts to the sample) using silver paint and connections were made to a function generator and multi-meter. For comparative measurements, two samples were glued in tandem with one alumina slide in between (FIG. 2B).

Materials used:

| Material | | Source |
|---|---|---|
| | D₃₃ piezoelectric | |
| | coefficient (pm/V) | |
| LiTaO₃ (Z-cut) | 8.8 ± 0.5 | MTI Corporation, USA |
| P-51 (Poled | 430 ± 2 | Shenzhen Yujie Electronics |
| Ceramic PZT) | | Co. ltd., China |
| | M₃₃ electrostrictive | |
| | coefficient (m²/V²) | |
| Ce_{0.95}Gd_{0.5}O_{1.95} | (1 ± 0.5) · 10⁻¹⁸ | Home made |
| (GDC5) pellet | | |

### Example 2

### Lock-in Ellipsometry Measurements

Measurements were performed on a manual null-ellipsometer with He—Ne laser light source (λ=632.8 nm), FIGS. 1A-1C. Voltage, U_{AC} (0-10V, 0.5 Hz-10 kHz) was applied to the sample using a function generator (DS345, Stanford Research), for samples with relatively low electro-mechanic coefficient, a high voltage amplifier (Trek 2205) was implemented. The ellipsometer photodetector was connected to a lock-in amplifier (SR830, Stanford Research) referenced to input from the function generator, in order to monitor the oscillating component of the photocurrent. Measurements were performed to characterize the dependence of the detector response on U_{AC} amplitude at fixed frequency and on U_{AC} frequency at fixed amplitude.

Since lock-in detection detects only the periodically varying ellipsometer signal, the measured response is resistant to signal drift due to temperature fluctuations, power supply ripple, or external mechanical vibrations. This stability is essential, given the small signal amplitude. In our experimental setup (FIG. 1A), the changes in the angular settings of the ellipsometer polarizer and analyzer, which correspond to changes in the RMS nanoampere current, are on the order of 10⁻⁴ degrees. The accuracy with which nanoampere current can be measured is far in excess of the accuracy with which a 10⁻⁴ degree rotation of the optical elements of the manual ellipsometer can be measured.

### Example 3

### Individual Sample Experiment

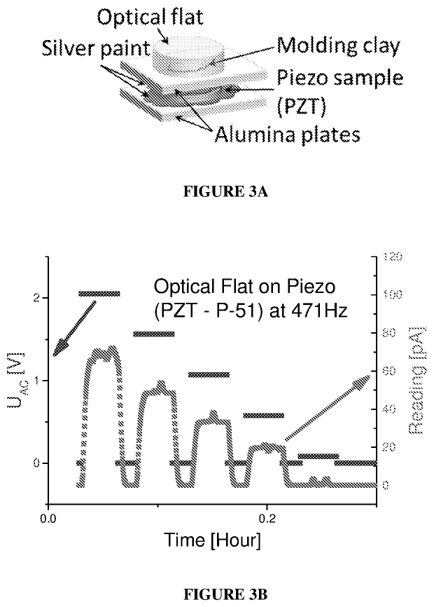

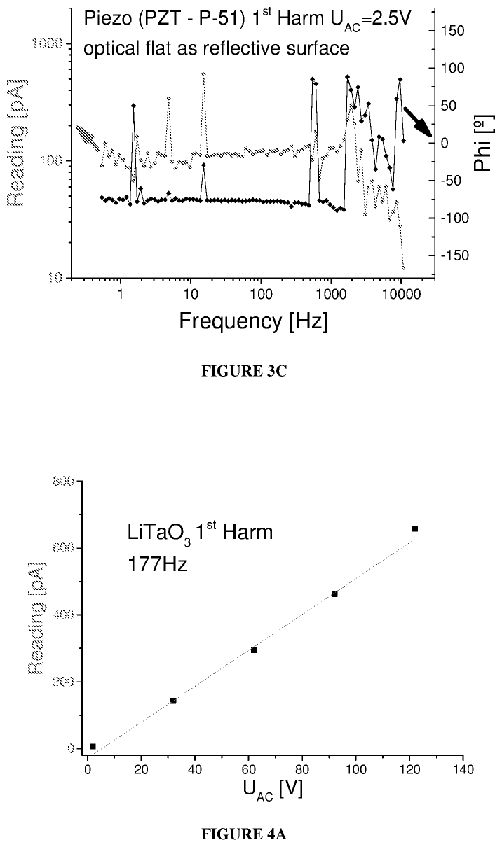

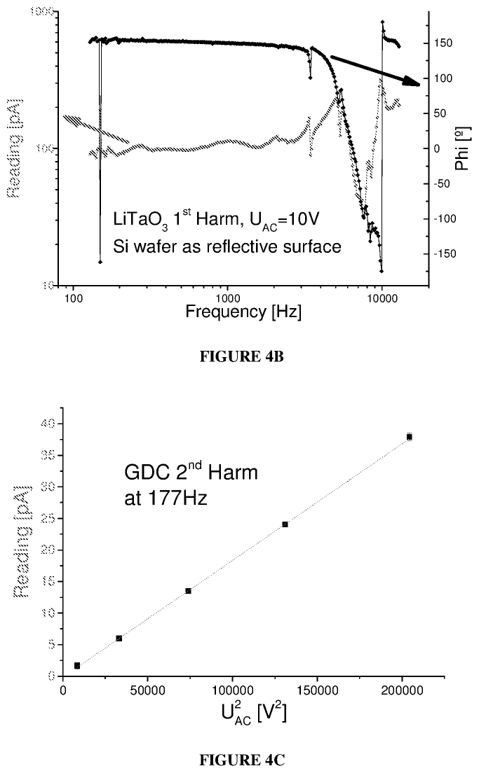

Application of U_{AC}≥0.08 V (177 Hz) on a PZT sample (FIG. 3A) generated a well detectable AC current in the ellipsometer photo-detector at the same frequency as U_{AC}, corresponding to vibrations of the reflecting surface of about 70 pm. The amplitude of the response scaled linearly with the amplitude of the voltage (FIG. 3B). Varying the frequency of U_{AC} (2.5V) gave a stable response over the range of 1.5 kHz-0.5 Hz while the amplitude of the vibration is about 2.2 nm (FIG. 3C) Similar results have been observed while measuring the response from LiTaO₃ single crystals with an even lower detection limit of 30 pm (in response to application of U_{AC}=2V at 177 Hz) (FIG. 4A), varying the frequency of U_{AC} (10V) gave a stable response over the range of 2.6 kHz-130 Hz while the amplitude of the vibration is about 160 pm (FIG. 4B). Being both piezoelectric materials, the measured response is indeed in correlation with the amplitude of the induced vibration. The same goes for the electrostrictive sample, GDC5, which gave clear quadratic dependence on the amplitude of U_{AC} (FIG. 4C).

The high sensitivity and wide measurable frequency range, without the ability to calibrate the response, contributes to qualitative investigation of unknown samples or extend the measurement conditions at which known samples are investigated.

### Example 4

### Comparative Measurements of Two Samples

In order to calibrate the measured optical response, two electromechanically active samples were glued in tandem (see FIG. 5A). Application of voltage to one sample and recording the optical response could be used for calibration of the response of the second sample; this is without moving any of the components from the setup. Yet, due to the complexity of the electromechanical response (for example, sheer and rotation components in addition to non-uniformities in the samples), it was essential to eliminate as many degrees of freedom as possible.

This was done using a door shaped apparatus that would only collect the vibration of each sample along the Z direction and translate it to oscillations in the degree at which the door is open (FIG. 5A, see details of the sample structure in FIG. 2B). Two samples of P-51 were installed onto this apparatus and measured at different angles of incidence. Even though the amplitude of the optical signal varied (FIG. 5B), the ration between the recorded optical responses of the top and the bottom PZTs was constant 1.74±0.21 (U_{AC}=6V at 471 Hz, measured at angles of 50°, 56°, 60°, 70°, 80°) (FIG. 5C). This constant is dictated by the mechanical properties of the setup (weight and size of the door) and not by the samples themselves.

With a single crystal LiTaO₃ replacing the top PZT sample, it was possible to calibrate the measured response from LiTaO₃ by that of the bottom PZT sample. The derived piezoelectric coefficient of single crystal LiTaO₃ is 9.9±1.5 pm/V, which is in good agreement with the value mentioned in literature 8.8±0.5 pm. The slope of the signal vs. applied voltage for the single crystal LiTaO₃ was divided by the corresponding slope for the reference PZT sample and then divided by the constant 1.74±0.21 (the ratio between the signal from the top and bottom identical PZT samples), then multiplied by the piezoelectric constant of the PZT, resulting as the piezoelectric constant of the single crystal LiTaO₃. Calculation details:

$$S l o p {e}_{L T O} = 0.0165 \pm 0.001 \frac{p A}{V} \\ S l o p {e}_{P Z T} = 0.42 \pm 0.04 \frac{p A}{V} \\ R a t i {o}_{L T O / P Z T} = \frac{S l o p {e}_{L T O}}{S l o p {e}_{P Z T}} = 0.039 \pm 0.004$$

$$Piezo . {const}_{P Z T} = 430 \pm 02 \frac{p M}{V}$$

$$System . const = 1.74 \pm 0.2$$

$$P iezo . cons {t}_{L T O} = \frac{R a t i {o}_{L T O / P Z T}}{S y stem . const} \cdot Piezo . {const}_{P Z T} = 9.9 \pm 1.5 \frac{p M}{V}$$

Another method used to measure expansion/contraction properties of a material uses the analyzer's angle as follows: the angle of the ellipsometer analyzer is used for calibration. In this approach two calibration plots are formulated to verify the correct quantification. First, a calibration plot A (change in intensity vs. change in analyzer's angle) is formulated using small variations of the analyzer's angle. Then a calibration reference is measured and calibration plot B is formulated (change in intensity vs. known displacement). The same steps are repeated for the investigated sample meaning measurement of calibration plot A (change in intensity vs. change in analyzer's angle) and the sample is measured and calibration plot B is formulated (change in intensity vs. unknown displacement). The pair of calibration plots A (change in intensity vs. change in analyzer's angle) are compared to verify that the initial measurement conditions are indeed identical and then the samples expansion/contraction is quantitated using the pair of calibration plots B. In this approach, the conditions of the sample measurement must remain identical to the calibration measurement (reflecting surface, beam alignment and ellipsometer angles).

The analyzer is an optical element in the system that is shifted in order to obtain better sensitivity.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A device for the measurement of expansion/contraction properties of a material, said device comprising:
a first sample comprising a first material, said sample comprising a first surface and a second surface;
a first substrate and a second substrate, connected to said first surface and to said second surface of said first sample respectively;
a second sample comprising a second material in contact with said second substrate;
a third substrate connected to said second sample;
a reflective material in contact with said third substrate.

2. The device of claim 1, further comprising an adhesive in contact with said third substrate and in contact with said reflective material such that said reflective material is attached to said third substrate via said adhesive material.

3. The device of claim 1, further comprising a first set of two electrical contacts each independently is in contact with said first sample and a second set of two electrical contacts each independently is in contact with said second sample.

4. The device of claim 1, further comprising a heating source for heating said first sample, said second sample or a combination thereof.

5. The device of claim 4, wherein said heating source comprises IR laser.

6. The device of claim 1, wherein one of said first material and said second material possesses known expansion/contraction properties and another of said first material and said second material possesses un-known expansion/contraction properties.

7. The device of claim 1, wherein said first material and said second material possess piezoelectric properties, electrostriction properties, thermal expansion properties or a combination thereof.

8. The device of claim 1, wherein said reflective material is reflective at a wavelength of 632.8 nm.

9. (canceled)

10. The device of claim 1, wherein the thickness of said sample ranges between 1 nanometer to 100 millimeters.

11. The device of claim 1, wherein the thickness of said substrate ranges between 10 micrometers to 100 millimeter.

12. The device of claim 2, wherein the thickness of said adhesive ranges between from 1 nanometer to 1 millimeter.

13. The device of claim 3, wherein the thickness of said electrical contacts ranges between from 1 nanometer to 10 millimeters.

14. The device of claim 2, wherein said adhesive material comprises modeling clay.

15. The device of claim 1, wherein said first substrate, second substrate or a combination thereof comprises alumina.

16. The device of claim 3, wherein said electrical contacts comprise Ag, Au, Cu, Pd, Pt, Sn or a combination thereof.

17. The device of claim 16, wherein said electrical contacts comprise conductive paint such as silver paint.

18. A method of measuring expansion/contraction properties of a material, said method comprising:
providing a device comprising:
a sample comprising said material, said sample comprising a first surface and a second surface;
a first substrate and a second substrate, connected to said first surface and to said second surface of said sample respectively;
a reflective material attached to said second substrate;
optionally two electrical contacts, each independently is in contact with said sample;
optionally a heating source for heating said sample;
optionally applying voltage to said sample using said electrical contacts;
optionally heating said sample;
illuminating said reflective material using a light source, such that said illumination comprises light having known and controllable polarization;
collecting light reflected off said reflective material;
measuring amplitude and phase of the oscillating change in polarization of the reflected light;
extracting parameters related to expansion/contraction from said reflected light measurement, thus evaluating said expansion/contraction properties of said material.

19. The method of claim 18, wherein said device further comprising an adhesive in contact with said second substrate and in contact with said reflective material such that said reflective material is attached to said second substrate via said adhesive material.

20. The method of claim 18, wherein said light source is a He—Ne laser.

21. The method of claim 18, wherein said collecting said reflected light is done using a detector.

22. The method of claim 18, wherein said method allows qualitative evaluation of said expansion/contraction properties.

23. A method of measuring expansion/contraction properties of a material, said method comprising:
providing a device comprising:
a first sample comprising a first material, said sample comprising a first surface and a second surface;
a first substrate and a second substrate, connected to said first surface and to said second surface of said sample respectively;
a second sample comprising a second material in contact with said second substrate;
a third substrate connected to said second sample;
a reflective material in contact with said third substrate;
optionally, a first set of two electrical contacts each independently is in contact with said first sample and a second set of two electrical contacts each independently is in contact with said second sample;
optionally a heating source for heating said first sample, said second sample or a combination thereof,
measuring said first sample, said measurement comprising:
optionally applying voltage to said first sample using said electrical contacts;
optionally heating said first sample using said heating source;
illuminating said reflective material with a light source, such that said illumination comprises light having known and controllable polarization;
collecting light reflected off said reflective material;
measuring amplitude and phase of the oscillating change in polarization of the reflected light;
extracting parameters related to expansion/contraction from said reflected light measurement, thus evaluating said expansion/contraction properties of said first material.
measuring said second sample, said measurement comprising:
optionally applying voltage to said second sample using said electrical contacts;
optionally heating said second sample using said heating source;
illuminating said reflective material with a light source;
collecting light reflected off said reflective material;
measuring amplitude and phase of the oscillating change in polarization of the reflected light;
extracting parameters related to expansion/contraction from said reflected light measurement, thus evaluating said expansion/contraction properties of said second material.
comparing parameters extracted from said first sample measurement to parameters extracted from said second sample measurement, thus evaluating said expansion/contraction properties of said first material, said second material or a combination thereof.

24. The method of claim 23, wherein said device further comprising an adhesive in contact with said third substrate and in contact with said reflective material such that said reflective material is attached to said third substrate via said adhesive material.

25. The method of claim 23, wherein said step of measuring said second sample is conducted prior to the step of measuring said first sample.

26. The method of claim 23, wherein one of said first material and said second material possesses known expansion/contraction properties and another of said first material and said second material possesses un-known expansion/contraction properties.

27. The method of claim 23, wherein said method allows quantitative evaluation of said expansion/contraction properties of said first material, said second material or a combination thereof.

28. The method of claim 23, wherein said quantitative evaluation comprises evaluation of the piezo-electric coefficient or electrostriction coefficient of said first material, said second material or a combination thereof.

29. An apparatus for the measurement of expansion/contraction properties of a material, said apparatus comprising:
a first device or a second device, wherein:
said first device comprising:
a sample comprising said material, said sample comprising a first surface and a second surface;
a first substrate and a second substrate, connected to said first surface and to said second surface of said sample respectively;
a reflective material in contact with said second substrate;
optionally two electrical contacts, each independently is in contact with said sample;
optionally a heating source for heating said sample;
said second device comprising:
a first sample comprising a first material, said sample comprising a first surface and a second surface;
a first substrate and a second substrate, connected to said first surface and to said second surface of said sample respectively;
a second sample comprising a second material in contact with said second substrate;
a third substrate connected to said second sample;
a reflective material in contact with said third substrate;
optionally, a first set of two electrical contacts each independently is in contact with said first sample and a second set of two electrical contacts each independently is in contact with said second sample;
optionally a heating source for heating said first sample, said second sample or a combination thereof;
light source for illuminating said reflective material;
a first polarizer for polarizing said light;
optionally a quarter wave plate;
a second polarizer for polarizing light reflected off said reflective material;
detector for collecting light reflected off said reflective material;
optionally a power supply for applying voltage to said sample,
means for measuring amplitude and phase of the oscillating change in polarization of the reflected light;
means for extracting parameters related to expansion/contraction from said reflected light measurement, thus evaluating said expansion/contraction properties of said material.

30. The apparatus of claim 29, said apparatus further comprising an adhesive in contact with said second substrate of said first device or in contact with said third substrate of said second device and in contact with said reflective material such that said reflective material is attached to said second substrate or to said third substrate via said adhesive material.

31. The apparatus of claim 29, wherein said apparatus comprises an ellipsometer.

32-35. (canceled)

36. The apparatus of claim 29, wherein said material of said sample(s) possesses piezoelectric properties, electrostriction properties, thermal expansion properties or a combination thereof.

37-48. (canceled)
